(19) United States
(12) Patent Application Publication
(10) Pub. No.: US 2026/0186073 A1
(43) Pub. Date: Jul. 2, 2026

(54) PROACTIVE FAULT DETECTION IN ELECTRIC VEHICLE SUPPLY EQUIPMENT SYSTEMS USING TIME SERIES ANALYSIS FOR SHAPELET DISCOVERY

(71) Applicant: PowerFlex Systems, LLC, San Diego, CA (US)

(72) Inventors: Justin ROETHLE, Wauwatosa, WI (US); Loic VALLANCE, San Diego, CA (US); Rajat SETHI, San Diego, CA (US)

(21) Appl. No.: 19/427,075

(22) Filed: Dec. 19, 2025

Related U.S. Application Data
(60) Provisional application No. 63/739,434, filed on Dec. 27, 2024.

(51) Int. Cl. G01R 31/40; B60L 53/62; B60L 53/68

(52) U.S. Cl. CPC G01R 31/40; B60L 53/62; B60L 53/68; B60L 2240/66

(57) ABSTRACT

Certain aspects of the present disclosure provide techniques for predicting a fault of an electric vehicle supply equipment (EVSE). An example method includes obtaining time series data associated with operation of one or more EVSEs; detecting one or more shapelets within the time series data; providing at least one shapelet of the one or more shapelets to a fault detection machine learning model pre-trained on shapelets to detect EVSE faults; and obtaining, as output from the fault detection machine learning model, an indication of a state of the one or more EVSEs.

### CROSS-REFERENCE TO RELATED APPLICATIONS

This Application claims the benefit of and priority to U.S. Provisional Ser. No. 63/739,434 , filed on Dec. 27, 2024, the entire contents of which are hereby incorporated by reference.

### INTRODUCTION

Electric vehicle (EV) charging infrastructure is a rapidly evolving field given the popularity of EVs. EV charging stations such as electric vehicle supply equipments (EVSEs) often rely on backend systems (e.g., local and/or cloud-based backend systems) to manage charging sessions. For example, when an EV connects to an EVSE, the EVSE sends a status update to a backend system, which then initiates and manages a charging session. The backend system maintains databases of active charging sessions across multiple sites and EVSEs. However, conventional EVSE systems, including such backend systems, currently lack the capability to predict faults before they occur. The conventional EVSE systems are generally reactive, where an alert may be triggered only after a fault has manifested. Such reactive systems fail to prevent system downtime and do not allow for efficient scheduling of preventive maintenance. As the EV charging infrastructure continues to expand, problems associated with reactive detection of faults in EVSE systems are expected to affect more users.

### SUMMARY

Certain aspects provide a method of predicting a fault of an EVSE. The method includes obtaining time series data associated with operation of one or more EVSEs; detecting one or more shapelets within the time series data; providing at least one shapelet of the one or more shapelets to a fault detection machine learning model pre-trained on shapelets to detect EVSE faults; and obtaining, as output from the fault detection machine learning model, an indication of a state of the one or more EVSEs.

Other aspects of the present disclosure provide one or more processing systems configured to perform the aforementioned method as well as those described herein; one or more non-transitory, computer-readable mediums comprising instructions that, when executed by one or more processors of one or more processing systems, cause the one or more processing systems to perform the aforementioned method as well as those described herein; a computer program product embodied on a computer readable storage medium comprising code for performing the aforementioned method as well as those described herein; and a processing system comprising means for performing the aforementioned method as well as those described herein.

The following description and the related drawings set forth in detail certain illustrative features of one or more aspects.

### DESCRIPTION OF THE DRAWINGS

The aspects set forth in the drawings are illustrative and exemplary in nature and not intended to limit the disclosure. The following detailed description of the illustrative aspects can be understood when read in conjunction with the following drawings, where like structure is indicated with like reference numerals and in which:

FIG. 1 depicts an example computing environment for predicting a fault of an EVSE, according to aspects provided herein;

FIG. 2 depicts a software configuration for an example edge environment for predicting a fault of an EVSE, according to aspects provided herein;

FIGS. 3A-3C depict example device configurations for an edge environment for predicting a fault of an EVSE, according to aspects provided herein;

FIGS. 4A-4C depict example hardware components that may be utilized for the devices from FIGS. 3A-3C, according to aspects provided herein;

FIG. 5 depicts a software configuration for an example cloud environment for predicting a fault of an EVSE, according to aspects provided herein;

FIG. 6 depicts an example system for predicting a fault of an EVSE, according to aspects provided herein;

FIG. 7 depicts an example process flow for predicting a fault of an EVSE, according to aspects provided herein;

FIG. 8 depicts an example system for predicting a fault of an EVSE, according to aspects provided herein;

FIG. 9 depicts a method for predicting a fault of an EVSE, according to aspects provided herein; and

FIG. 10 depicts an example processing system configured to perform the methods described herein.

### DETAILED DESCRIPTION

Aspects disclosed herein include systems and methods for predicting a fault of an EVSE. Some aspects utilize time series analysis and shapelet discovery or detection techniques to predict faults in EVSE systems before they occur. By analyzing historical data on electrical metrics, weather conditions, and/or usage patterns, etc. alongside optimization set points, certain aspects may identify or detect “shapelets” (e.g., patterns) of data indicative of impending faults. Aspects of systems and methods for predicting a fault of an EVSE, incorporating the same, will be described in more detail, below.

There are several technical challenges associated with systems and methods for detecting a fault of an EVSE. For example, some systems and methods for detecting a fault of an EVSE rely on reactive alerting systems that notify operators after (e.g., only after) a fault has occurred. Such reactive approach may increase system downtime and may lead to inefficient maintenance schedules, potentially resulting in customer dissatisfaction. Moreover, as such reactive alerting systems rely on basic alerting methodologies that trigger alerts after (e.g., only after) faults are detected, they lack the ability to preemptively identify potential faults, resulting in missed opportunities for preventive maintenance and for reduced system downtime.

As an example of a reactive fault detection system, some EVSE monitoring systems may rely (e.g., predominantly) on reactive fault detection methods. These systems may generate alerts after (e.g., only after) a fault has occurred or when certain performance metrics exceed predefined thresholds. However, there are several issues with such reactive fault detection system. First, there is a lack of proactivity. The reactive systems do not provide early warnings, resulting in unplanned downtime and inefficient maintenance scheduling. Second, the predefined thresholds are used for basic threshold-based alerts that may not capture complex patterns or subtle precursors to faults. Third, response to any detected fault may be delayed. Since any alerts based on detected faults are generated post-fault, there may be no opportunity for preventive maintenance.

As another example, some systems may utilize threshold-based monitoring and basic statistical methods. Some systems may employ fixed thresholds for parameters like voltage, current, or temperature. Basic statistical methods such as monitoring mean values, standard deviations, and trends may be used to detect anomalies in EVSE behavior. However, there are several issues with such threshold-based monitoring and basic statistical methods. First, they lack flexibility. Fixed thresholds may not adapt to varying operating conditions, potentially leading to false positives or missed detections. Second, they are overly simplified. Basic statistical methods may not detect complex temporal patterns or sequences that indicate impending faults.

As yet another example, some systems may utilize vendor-specific diagnostic tools. Some EVSE manufacturers may provide proprietary diagnostic and monitoring tools tailored to their equipment. These tools may include basic fault detection and alerting mechanisms. However, there are several issues with such vendor-specific diagnostic tools. First, they lack standardization, where such tools are specific to a single vendor's hardware and may not be compatible with other systems. Second, they do not provide predictive capability, where they may focus on current system status rather than predictive analytics. Third, they may create data silos, where such proprietary tools may not integrate with external data sources, limiting the scope of analysis.

As yet another example, some systems only provide basic or limited time series analysis. Simple time series analysis methods, such as moving averages or exponential smoothing, have been used to identify trends and anomalies in EVSE data. However, there are several issues with such limited analysis. First, there is insufficient depth in analysis, where basic methods may not capture complex patterns or sequences that precede faults. Second, there are scalability issues, where such limited analysis may not scale well with high-frequency data from multiple EVSE units. Third, such limited analysis lacks advanced techniques, limiting the ability to detect subtle indicators of faults.

As yet another example, some systems may be rule-based systems. Such systems may use a set of predefined rules to detect potential faults based on specific conditions or combinations of parameters. However, there are several issues with such rule-based systems. First, such systems have a rigid structure, where they lack flexibility and may not adapt well to new fault patterns or evolving system behaviors. Second, such systems may create maintenance overhead, where updating and maintaining the rule set can be labor-intensive and may not keep pace with changing data. Third, such systems may have scalability limitations, where, as the number of rules grows, the systems can become cumbersome and less efficient.

As yet another example, some systems may perform anomaly detection using unsupervised learning. Some approaches may employ unsupervised learning techniques, like clustering or principal component analysis (PCA), to detect anomalies without labeled fault data. However, there are several issues with such anomaly detection. First, it lacks specificity, where unsupervised methods may identify anomalies but may not always distinguish between benign anomalies and precursors to faults. Second, there may be a lot of false positives, leading to alert fatigue and inefficient use of maintenance resources. Third, there may be interpretability issues, where results from unsupervised models may be difficult to interpret, making it challenging for support teams to act on them.

Accordingly, improved systems and methods for detecting or predicting a fault of an EVSE may be desired, to mitigate the technical challenges discussed above, such as the reactive nature of some systems, insufficient data analysis, scalability challenges, hardware variability, and false positive management.

Certain aspects of the present disclosure adopt a proactive approach to detecting or predicting a fault of an EVSE. Unlike the reactive alerting systems, some aspects of the present disclosure may leverage data analysis and machine learning techniques to predict faults. Such proactive approach to detecting or predicting a fault of an EVSE may mitigate the technical challenges described above with reference to some systems, and may provide a significant improvement in system reliability and maintenance efficiency. Certain aspects of the present disclosure provide a proactive fault detection system for EVSE that leverages advanced time series analysis, including shapelet discovery or detection techniques, to predict faults before they occur. By integrating high-frequency operational data, environmental conditions, and usage patterns, some aspects may identify unique patterns in the data—known as shapelets—that signal impending equipment failures. A shapelet may be a subsequence of time series data, and a shapelet may be correlated with an equipment failure, such that when such a shapelet is detected, there is usually an equipment failure that follows. This may enable operators to perform preventive maintenance, reducing downtime and enhancing system reliability. The solutions described herein may be adaptable to various EVSE hardware types, may integrate heterogeneous data sources into a unified analytical framework, and/or may utilize scalable cloud computing resources for efficient processing. In certain aspects, the systems and methods described herein may transform EVSE maintenance from a reactive process into a proactive one, offering significant technical advantages over existing solutions.

For example, certain aspects of the present disclosure may use time series data classification for shapelet discovery or detection. Some aspects may process data (e.g., time series data) from a plurality of diverse data sources, including, for example, EVSE metrics and environmental data, to identify predictive signatures (e.g., shapelets). In certain aspects, the systems and methods described herein operate, at least in part, on cloud computing infrastructure or environment, where a periodic job (e.g., cron job) may analyze data (e.g., recent data) to discover or detect new shapelets and update predictive models. Fault predictions may be stored in a data storage component (e.g., a database). In certain aspects, the fault predictions may be provided to a support team (e.g., of support engineers) as part of a user interface, where the fault predictions may be displayed (e.g., visualized) on the user interface. Such fault predictions may enable one or more preemptive actions to prevent faults.

Certain aspects of the present disclosure provide a solution to the technical challenge(s) relating to the variability in EVSE hardware and the difficulty in generalizing fault patterns across different systems. By focusing on high recall in predictions, the systems and methods described herein may ensure that likely fault scenarios are closely monitored, even at the expense of potential false positives, which may be managed through targeted monitoring strategies. For example, the systems and methods described herein may achieve a balance between high recall (completeness of positive predictions) and high precision (accuracy of positive predictions) in fault monitoring, such that in certain cases, the tradeoffs between precision and recall may be configurable. In some cases, while high precision may be weighted higher at first, while the systems and methods may then be expanded to target higher recall.

Accordingly, some aspects of the present disclosure may utilize time series analysis for shapelet discovery or detection to proactively identify shapelets indicative of upcoming faults. The systems and methods described herein may provide several technical benefits, such as: (1) higher recall in fault prediction, enabling operators to monitor potential fault candidates closely; (2) reduction in unnecessary downtime by allowing preventive maintenance before faults occur (e.g., based on the detected or identified signatures indicative of the upcoming faults); and (3) customization and adaptability to specific EVSE hardware, enabling detection of unique fault patterns across different EVSE or system types and sites. Accordingly, some technical challenges that may be overcome by certain aspects of the present disclosure include: (1) adaptability to various EVSE hardware types and their unique fault patterns; (2) integration and analysis of heterogeneous data sources for comprehensive fault prediction; and (3) real-time application of predictive models for dynamic fault detection and system monitoring.

Accordingly, certain aspects of the present disclosure may offer significant advantages over some systems by transforming EVSE fault detection from a reactive process to a proactive process. Examples of such advantages may include: (1) advanced analytical capabilities, where utilization of high-frequency time series analysis, such as for shapelet discovery or detection, may enable the detection of complex fault precursors that other systems may miss; (2) comprehensive data integration, where a wide range of data sources may be incorporated for a holistic analysis, improving prediction accuracy; (3) adaptability and scalability, where certain aspects of the present disclosure may be designed to handle hardware variability and scalable to accommodate growing data volumes and evolving technologies; (4) enhanced accuracy with supervised learning, where sophisticated algorithms may be combined with human-in-the-loop processes to manage false positives and continuously improve model performance; and (5) operational efficiency, where downtime and maintenance costs may be reduced through proactive scheduling and efficient resource allocation.

The predictive capability of certain aspects may allow for proactive monitoring and maintenance, significantly improving system reliability and uptime. Some aspects may address the technical challenge of predicting EVSE faults before they occur to improve uptime and reliability. Accordingly, certain aspects may solve the technical problem of early fault detection by analyzing historical time series data, including offered current (e.g., current set point, which is the current level the EVSE is configured or set to draw, though the actual current draw/delivery may be different), delivered current, voltage, connector status, connection status, contactor status, offered power (e.g., power set point, which is the power level the EVSE is configured or set to draw, though the actual power draw/delivery may be different), delivered electricity or energy (e.g., in Kilowatt-hour (kWh)), and EVSE status alongside environmental factors like weather and usage patterns.

### Example Computing Environment

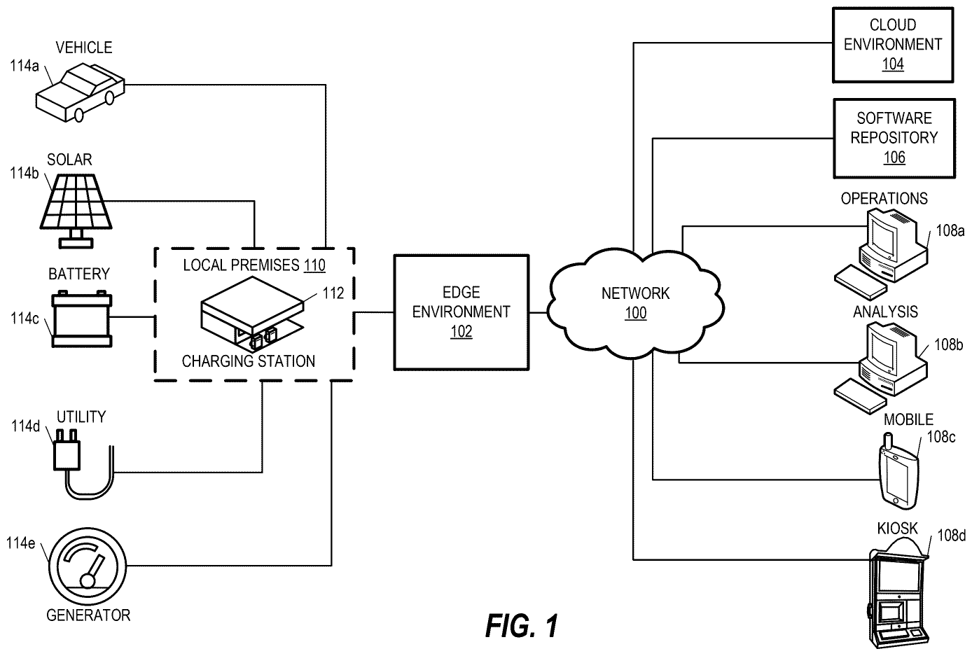

Referring now to the drawings, FIG. 1 depicts an example computing environment for predicting a fault of an EVSE, according to aspects provided herein. As illustrated, the computing environment includes a network 100 that is coupled to an edge environment 102, a cloud environment 104, a software repository 106, as well as one or more ancillary devices 108 (including an operations device 108a, an analysis device 108b, a mobile device 108c, and/or a kiosk device 108d). The network 100 may be configured as any wide area network (WAN, such as the internet, power network, cellular network, etc.) or other network for facilitating communication among the edge environment 102, the cloud environment 104, the software repository 106, and the ancillary devices 108.

Edge environment 102 may generally be deployed at a local premises site 110 (also referred to herein as a site) to provide various services, including coordination and optimization of one or more energy assets 114 (including an EV 114a, a solar device 114b, a battery energy storage system (BESS) 114c, a utility grid 114d, and/or a generator 114e), such as charging of electric vehicles (e.g., EV 114a) using charging station 112 and controlling one or more of various distributed energy resources (DERs), such as solar device 114b, BESS 114c, utility grid 114d, and/or generator 114e (e.g., an on-site diesel, natural gas, or other type of fueled generator). Generally, the aforementioned DERs may provide energy to the charging station 112 and/or use energy from the charging station 112 (e.g., by way of a backflow of energy from EV 114a to other aspects of site 110). In some aspects, charging station 112 may send excess energy back to the BESS 114c and/or to utility grid 114d. Generally, edge environment 102 may monitor and/or modify the energy sent to and received from the DERs to optimize various tasks, such as charging of EV 114a.

Charging station 112 may utilize one or more of various communication protocols, such as open smart charging protocol (OSCP), open charge point interface (OCPI), ISO 15118, OpenADR, open charge point protocol (OCPP), etc. and may represent Level 1, Level 2, Level 3 (e.g., DC Fast Charging), and higher level charging stations, as applicable. Generally, the “level” of a charging station refers to the power level and/or ability to provide electric power to a device being charged.

Edge environment 102 is configured as an interface between various aspects of site 110 and network 100. In various aspects, compute resources for performing different functions at a site, such as control or optimization of EV charging, may be split between local compute resources in edge environment 102 and remote compute resources, e.g., in cloud environment 104 of FIG. 1.

Cloud environment 104 is coupled to the edge environment 102 via the network 100 and may be configured for further processing of data, as described herein. While FIG. 1 depicts a single cloud environment 104 that serves a single edge environment 102, this is merely an example, as some aspects may be configured such that the cloud environment 104 may serve a plurality of edge environments 102 that each serve one or more sites 110, one or more charging stations 112, one or more DERs, and the like.

Software repository 106 is also coupled to site 110 via network 100. Software repository 106 may be configured as a platform to program, store, manage, control changes, etc. to software that is implemented in edge environment 102 and/or cloud environment 104. In some aspects, software repository 106 may be configured as a proprietary service and/or may be provided by a third-party, such as GitHub™. Additionally, some aspects may be configured such that the software repository 106 is provided by the same entity that manages the cloud environment 104. As such, these aspects may be configured such that software repository 106 and cloud environment 104 may be combined.

With respect to the ancillary devices 108, the operations device 108a may be utilized to monitor and/or alter operations of the computing environment provided in FIG. 1. The analysis device 108b may analyze utilization, operation, charging, and/or other features of the computing environment provided in FIG. 1. The mobile device 108c may represent an administrator device and/or a user device. As a user device, the mobile device 108c may initiate charging, perform payment, and/or perform other user-specific actions. As an administrator device, the mobile device 108c may perform administrative operations, analysis, and/or other actions. The kiosk device 108d may be located at one of the charging stations 112 and/or remote therefrom and may provide user-specific or administrative actions, similar to that of the mobile device 108c. In some aspects, one or more administrators may use the kiosk device 108d to view information about a site or make changes. As will be understood by one of ordinary skill in the art, the ancillary devices 108 may each include one or more processors, one or more memory components, and/or other hardware and/or software for performing the functionalities provided herein. It should be understood that while the kiosk device 108d is depicted as being remote from the site 110, some aspects may not be configured in this manner. Specifically, some aspects may utilize a kiosk device 108d that is local at the site 110, which may communicate via a local network and/or the network 100 for providing the services described herein.

### Example Edge Environment

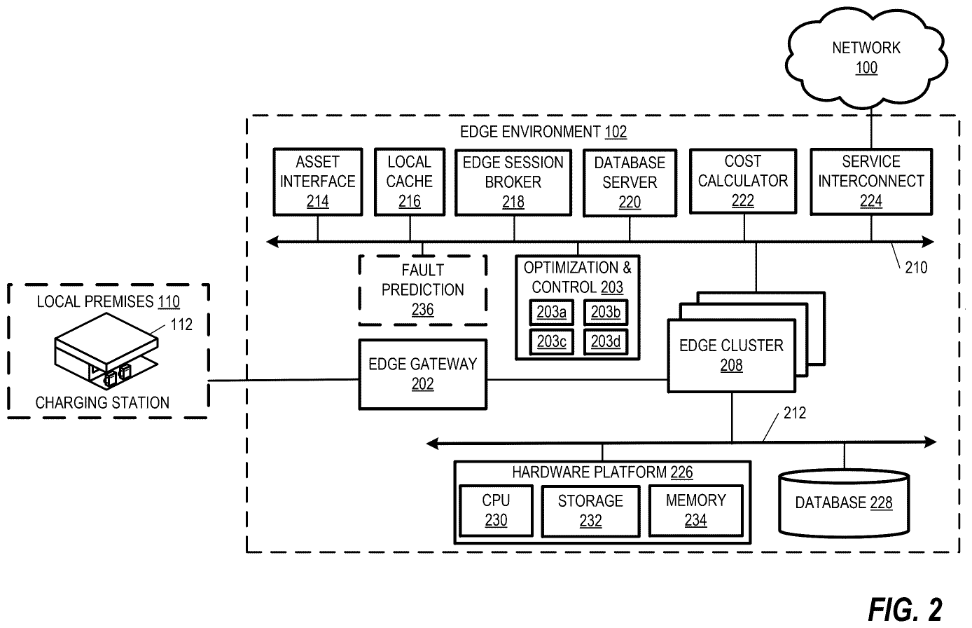

Referring now to FIG. 2, the edge environment 102 may be coupled to the site 110 via an edge gateway 202. Edge environment 102 may be operatively coupled to aspects of site 110, such as charging station 112 via edge gateway 202. Edge environment 102 further includes an edge cluster 208, which is coupled to communication bus 210 and hardware bus 212. Communication bus 210 is coupled to optimization and control manager 203, asset interface 214, local cache 216, edge session broker 218, database server 220, cost calculator 222, and service interconnect 224 in this example. In certain aspects, communication bus 210 may also optionally be coupled to a fault prediction component 236 (e.g., server). Hardware bus 212 is coupled to hardware platform 226, which may include one or more processors, such as CPU 230, one or more storage components 232, one or more memory components 234, and/or other hardware components. Also coupled to hardware bus 212 is database 228. Though certain components (e.g., cost calculator 222, database server 220, etc.) of edge environment 102 are depicted separate from hardware platform 226, they may be services or processes configured to run on hardware platform 226. Further, though certain components are illustrated as separate components, the functionality of such components may be combined into a single component and/or further divided among additional components.

Communication bus 210 and hardware bus 212 may be utilized to facilitate operation of all services that run in edge environment 102 and communicate with each other via a distributed message streaming system. The coupling of the aforementioned services may be accomplished in some aspects via a distributed message streaming system, such as NATS.

In the depicted example, charging station 112 is configured for communication with edge environment 102 via edge gateway 202, such as via a short-range wireless network technology, such as via a Zigbee® PAN. The edge gateway 202 may be configured to receive data, such as electric vehicle charging data, price change data, vehicle data, etc. from the charging station 112 and/or vehicles that are being charged via the connection with the site 110 (of FIG. 1).

In some aspects, edge gateway 202 may be configured to abstract data received from various aspects of site 110 (of FIG. 1), such as charging station 112, to remove protocol-specific distinctions. For example, a first charging station may utilize a first communication protocol and/or billing protocol and a second charging station may utilize a second communication protocol and/or billing protocol. Edge gateway 202 may receive data packets from both the first charging station using the first communication protocol and the second charging station using the second communication protocol and may transform the received data into a protocol-agnostic format prior to providing the data to edge cluster 208. This may allow wide interoperability between edge environment 102 and various types of hardware (e.g., charging station 112) at a site.

Edge cluster 208 is the central message center in various aspects. For example, when a user plugs a vehicle into a charging station 112, edge cluster 208 receives data from edge gateway 202, parses that data (e.g., to generate access state data) and causes the state data to be sent to the database server 220. Edge cluster 208 also receives the data and creates a session entry, which may be stored in the local cache 216. Edge cluster 208 may additionally send the session entry to the cloud environment 104 (of FIG. 1) via network 100. Edge session broker 218 may also receive data related to the new session and may query database server 220 to access additional session data to determine charging characteristics for charging station 112.

The edge session broker 218 may produce data or signals that are sent to the edge cluster 208, which may be sent to the edge gateway 202 for potentially sending back to one or more of the charging stations 112. Information that may be reported might include current delivered over time (e.g., amperes), total energy delivered (e.g., kWh), power delivered over time (e.g., kW), voltage at the charging station over time (e.g., V), charging station state (e.g., connected, disconnected, offline), connectivity state, charging state, etc. The charging stations 112 may report any errors back to the edge cluster 208. The cost calculator 222 may be engaged to access pricing data from the cloud environment 104 and may calculate costs incurred based on delivered energy, expected costs prior to charging, idle time interval, parking time interval, etc. The asset interface 214 may be a software interface between the edge environment 102 and the energy assets 114.

Edge cluster 208 may be configured such that any message received by the edge cluster 208 may also be sent to the cloud environment 104 (of FIG. 1) for consumption by a data subscriber in the cloud environment 104. For example, if a user of the mobile device 108c (in FIG. 1) desires to claim a charging session, mobile device 108c does not need to access edge environment 102 directly. Instead, mobile device 108c may connect with the cloud environment 104 (of FIG. 1), which sends a message to the edge cluster 208 with an instruction to claim the session. Service interconnect 224 is configured for establishing an HTTP, TCP, and/or other type of communication with the cloud environment 104 (of FIG. 1) via network 100.

The optimization and control manager 203 may provide energy optimization and adaptive load management (ALM) functions, for example, for various energy assets 114 at the site 110 (of FIG. 1). For example, the optimization and control manager 203 may be responsible for calculating set-points for each asset for the energy optimization and ALM amongst the energy assets 114 and providing data related to the calculated set-points to the asset interface 214. A set-point may be a value for a parameter (or a set of values for a set of parameters), such as a charging rate. In certain aspects, the optimization and control manager 203 may include a database layer 203a to store data related to site configurations; an orchestration layer 203b to gather data, trigger optimizations, and/or issue set-points (e.g., provide the calculated set-points to energy assets); an optimization layer 203c to formulate and solve optimization problems to calculate set-points; and/or a control layer 203d for higher frequency feedback based controls (e.g., for modifying set-points to respond to fast time-scale events).

Optimization and control manager 203 may determine when optimization set-points need to be updated. Examples of when optimization set-points need to be updated include, but are not limited to: (1) when a new energy asset is installed at a site, (2) when a new vehicle to be charged arrives at a site, (3) when a measured value such as load or generation changes, (4) when a system parameter such as the target energy for a vehicle is updated, (5) when an external event occurs (such as a demand response event), and/or (6) at a fixed cadence (e.g., every 5 minutes). When it is determined that the optimization set-points need to be updated, optimization and control manager 203 may collect data needed for optimization, including optimization configuration from the cloud environment 104 of FIG. 1 (which can also be cached at edge environment 102) and state information from edge environment 102 and/or cloud environment 104. Examples of the optimization configuration include, but are not limited to: network and equipment constraints, optimization parameters such as the precision and timeout settings, etc. In certain aspects, the state information from edge environment 102 and/or cloud environment 104 includes the states of the energy assets, as well as other state information including EV driver preferences, price signals, and grid signals. Further, optimization and control manager 203 may perform optimization to calculate new/updated set-points. In certain aspects, optimization and control manager 203 may (e.g., optionally) run a fast time-scale control loop which adjusts set-points in real-time in response to fast changing signals, such as building load, solar generation, or grid signals. In some aspects, the functionalities of the optimization and control manager 203 may be implemented, at least in part, within the cloud environment 104 (of FIG. 1).

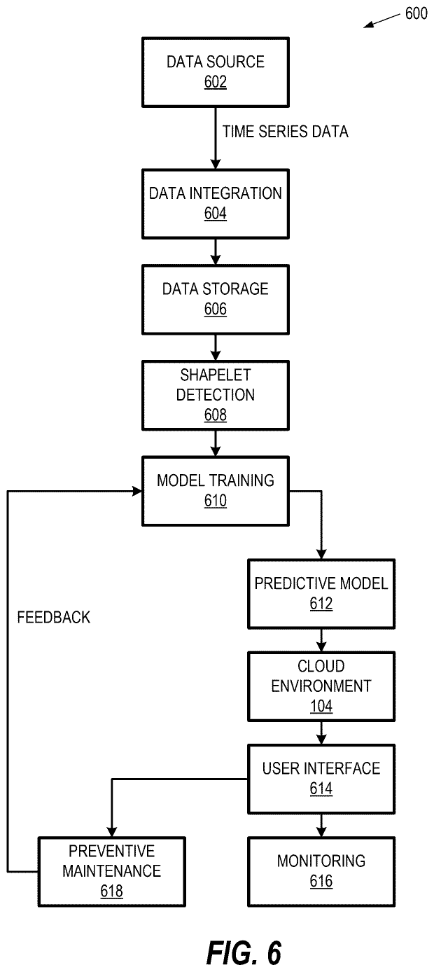

In certain aspects, the fault prediction component 236 may implement one or more functions of a fault prediction system that is described further herein with reference to, for example, FIGS. 6-8 by utilizing one or more components of the edge environment 102 described herein. In some aspects, the fault prediction system may not utilize any component or compute resources of the edge environment 102, such that the fault prediction component 236 may not exist in the edge environment 102. Such fault prediction system may utilize one or more components and compute resources of the cloud environment 104 to implement its functions or other compute resources.

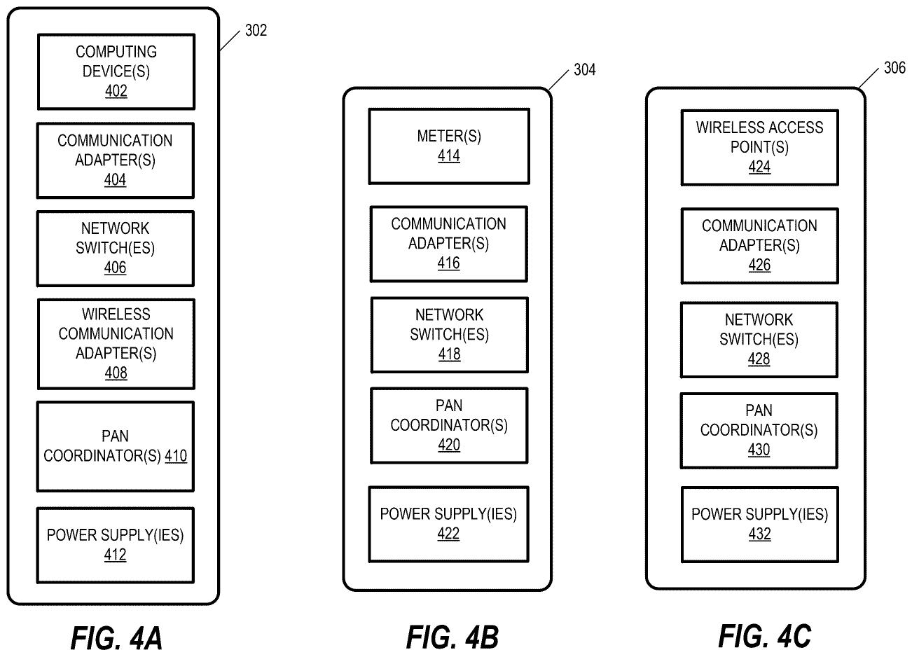

Hardware platform 226 represents any hardware for facilitating the processes and actions described herein. Specifically, one or more CPUs 230 may represent one or more types of processing device configured for executing instructions. One or more storage components 232 may be configured as long term storage, such as a hard drive or the like. One or more memory components 234 may include any of various types of random access memory or the like. One or more databases 228 may be configured for additional storage and may be housed with the other hardware and/or elsewhere. Examples of different hardware platforms that may be deployed in edge environment 102 are described further below with respect to FIGS. 4A-4C.

### Example Hardware Configurations for Edge Environment

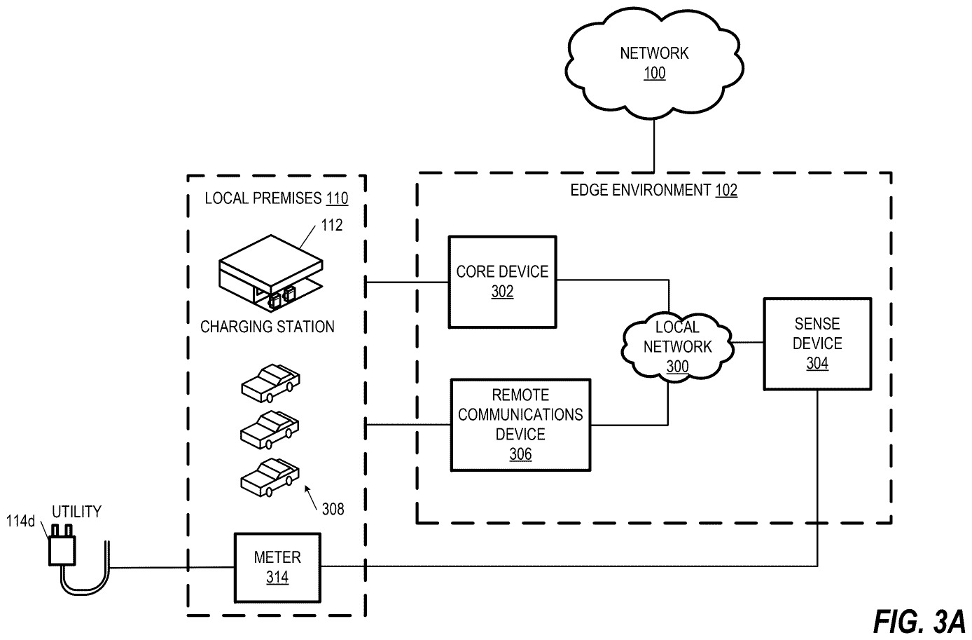

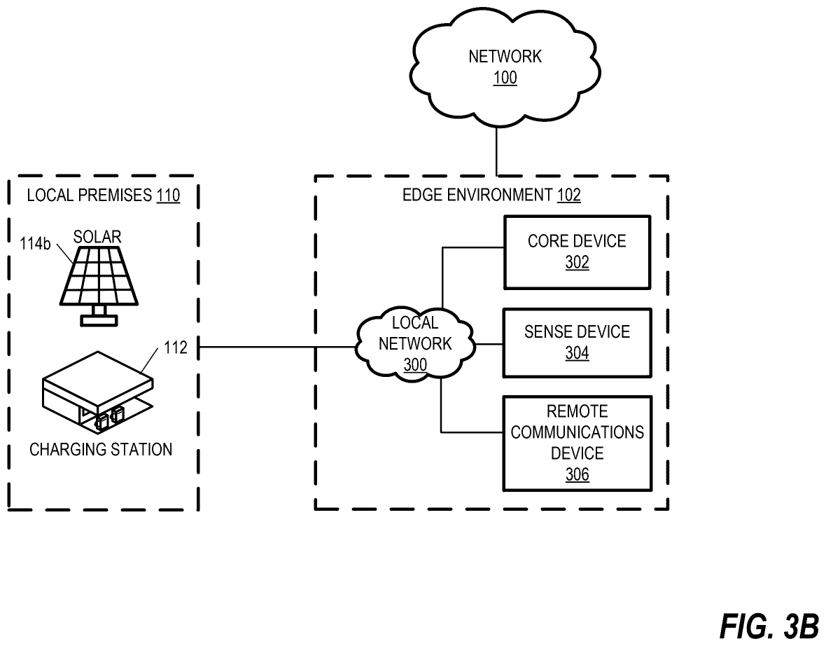

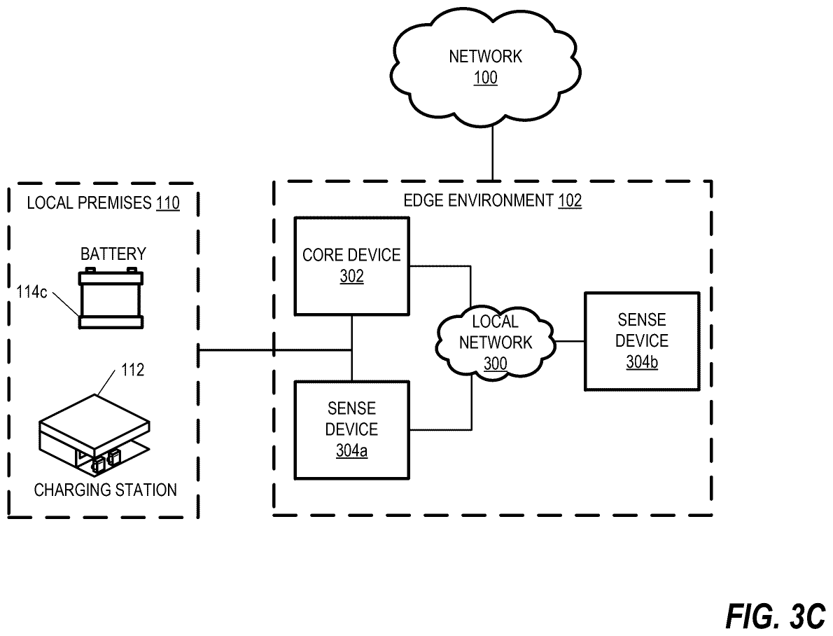

FIGS. 3A-3C depict example device configurations for edge environment 102, according to aspects provided herein. Specifically, FIG. 3A depicts a charging solution. As illustrated, the charging station 112 is coupled to a local network 300 via a core device 302. The local network 300 may include any local area network, Ethernet, PAN, etc. The core device 302 may be physically installed within communications range of one or more chargers in the charging station 112. A sense device 304 may be installed, for example, in an electrical room or in another enclosure with electrical equipment of the charging station 112 and/or one or more energy assets 114 to monitor the main metering point for the local utility point of common coupling. This may enable one or more algorithms to provide the optimal dispatch of EV charging power, subject to local energy rates and the vehicles currently charging. In the case that there are vehicles 308 using EV chargers that are out of communications range of the core device 302, such as a sub-level of a parking garage, one or more remote communications devices 306 may be included. In certain aspects, at least one of the one or more remote communications devices 306 may be in data communication with the charging station 112 (e.g., having one or more EV chargers charging one or more vehicles 308) and/or vehicles 308. Also included at the site 110 is a meter 314 for communicating energy with the utility grid 114d.

The core device 302 shown in FIG. 3A is the central processing device and serves as the communications hub. In certain aspects, the components of FIG. 2 may generally operate, at least in part, as part of the core device 302. The core device 302 may provide optimization, load management, communication coordination, fault prediction, and/or data historian services. The core device 302 may communicate with the cloud environment 104 via cellular modem, wired internet service provider (ISP), and/or other communications medium to get current optimization and load management set-points for charging stations 112 and/or other assets, such as via an optimization algorithm that may be stored locally and/or at the cloud environment 104. It will be understood, however, that some aspects may be configured such that the core device 302 performs optimization locally. In certain aspects, the core device 302 dispatches these set-points, through a local communications protocol (e.g., Wi-Fi) and/or via the remote communications device 306 to reach locations that are distant or hard to reach, such as charging stations with a core device 302 and/or sense device 304 at sub-levels of a parking garage or a rooftop solar inverter. The core device 302 may additionally or alternatively collect data directly from distributed energy resources and power measurement devices or through cloud-based communications with the network 100.

Power and energy metering data may be collected via the sense device 304. The sense device 304 may include a smart meter with support for multiple single-and three-phase loads, such as with a local historian and Ethernet communication back to the device via the local network 300. The sense device 304 may also incorporate support for additional devices running on the edge including but not limited to thermocouple wiring, weather stations, temperature sensors, pyranometers, etc. It should be noted that additional sense devices 304 and remote communications devices 306 can be added to handle a variety of situations, such as a separate subpanel for energy metering of a new solar system or for monitoring of a new inverter associated with a rooftop solar installation.

FIG. 3B depicts a solar application where the core device 302 and the sense device 304 are installed in an electrical room or other common area. The sense device 304 can monitor the main metering point for the local utility as well as the solar production at tie-in breakers for the solar device 114b. The remote communications device 306 may be installed in a position to communicate directly with the solar device 114b and report the data received from the solar device 114b to the core device 302. Accordingly, the core device 302, the sense device 304, and the remote communications device 306 depicted in FIG. 3B may perform similar functions as those devices depicted in FIG. 3A.

FIG. 3C depicts a battery application where the core device 302 and the sense device 304 (including a first sense device 304a and a second sense device 304b) are installed physically near the BESS 114c. In some cases where the BESS 114c is near the point of common coupling with the utility grid 114d, a single sense device 304a can monitor the full site. In some cases where there is a significant distance to the metering point for the utility grid 114d, the second sense device 304b (or a plurality of second sense devices 304b) may be installed near the utility meter, such as the electrical room.

### Example Hardware Components in Core, Sense, and Remote Communications Devices

FIGS. 4A-4C depict example hardware that may be utilized for the devices from FIGS. 3A-3C, according to aspects provided herein. Specifically, FIG. 4A depicts hardware components that may be present in core device 302. In some aspects, the core device 302 is the brain where the energy optimization and adaptive load management (ALM) functions (e.g., by the optimization and control manager 203 of FIG. 2) and/or fault prediction are executed and dispatched. As illustrated, the core device 302 may include one or more computing devices 402, one or more communication adapters 404, one or more network switches 406, one or more wireless communication adapters 408, one or more PAN coordinators 410, and/or one or more power supplies 412. As will be understood, the computing device(s) 402 may include one or more processors, one or more memories, and/or other components that a conventional, specific-purpose machine may utilize. In some aspects, the computing device(s) 402 may include power line communication (PLC) infrastructure, while some aspects may utilize retail and/or micro-industrial computer components for optimization, load management, communication coordination, and/or historian services.

The communication adapter(s) 404 may be configured for load balancing and otherwise managing communications of, for example, Modbus RTU (RS485) to Modbus TCP (Ethernet) or Ethernet IP (RJ45) to Ethernet Optical (SFP), etc. The network switch(es) 406 may be configured for routing of network traffic, and may be configured as an Ethernet switch for communication to other nodes (e.g., the sense device 304, the remote communications device 306, and/or other core device 302), distributed energy resources, and/or energy based management systems.

The wireless communication adapter(s) 408 may include a cellular modem, internet modem, Wi-Fi access point, etc. for facilitating wireless communications to the internet or other wide area network. Similarly, the PAN coordinator(s) 410 may be configured to create and/or join communication connections with other devices. This may include a Zigbee coordinator, Bluetooth device, and/or other device for performing this function. The power supply(ies) 412 may be configured as battery power, connection to external power, etc.

FIG. 4B depicts hardware components of the sense device 304 from FIGS. 3A-3C. The sense device 304 may be configured as a smart-metering piece for collection and storage of power/energy data such as measurements such as temperature, voltage, current, power, solar irradiance, wind speed, etc. The sense device 304 may include a smart meter with multiple channels of measurement that may comprise single-phase circuits and/or three-phase circuits. The sense device 304 may communicate meter data back to the core device 302 from meter locations such as electrical rooms, rooftop solar installations, EV chargers, and subpanels. Certain aspects may be optimized for ease of installation and reduced intrusion to the site. Power over Ethernet (PoE) sourced from the core device 302 may suffice for most installations. The sense device 304 may transmit data back to the core device 302 via a network switch. The sense device 304 may be optimized to utilize minimal power, and PoE may be acceptable for most installations.

As illustrated in FIG. 4B, the sense device 304 includes one or more meters 414, one or more communication adapters 416, one or more network switches 418, one or more PAN coordinators 420, and/or one or more power supplies 422. The power supply(ies) 422 may include a power interface for providing power to the sense device 304. In certain aspects, the meter(s) 414 may be power meter(s) utilized for monitoring single-phase and three-phase loads of power. The communication adapter(s) 416 may be utilized for facilitating communications between the sense device 304 and other devices. The network switch(es) 418 may be a PoE enabled switch for communication. Similarly, the PAN coordinator(s) 420 may create and/or join personal area networks, such as via Zigbee, Bluetooth, and the like. In some aspects, PoE or other power source may be utilized.

As illustrated in FIG. 4C, the remote communications device 306 may be a network-connectivity extension, for example, for EV charging or solar monitoring locations where Zigbee, Wi-Fi, or Ethernet is being extended to remote or difficult-to-reach locations such as remote subpanels, parking garage levels, or rooftop inverters. Some aspects are optimized for ease of installation and reduced intrusion to the site where PoE may suffice for most installations from the core device 302. The remote communications device 306 may be configured to transmit data back to the core device 302 via a network switch.

Specifically, the remote communications device 306 may include one or more wireless access points 424, one or more communication adapters 426, one or more network switches 428, one or more PAN coordinators 430, and/or one or more power supplies 432. The wireless access point(s) 424 may be configured to extend wireless communication signals to chargers and/or other intelligent electronic devices. The communication adapter(s) 426 may be configured for facilitating communications between the remote communications device 306 and other devices. The network switch(es) 428 may be configured as a PoE Ethernet switch and/or other network switch for communicating with the core device 302. The PAN coordinator(s) 430 may be configured to create and/or join personal area networks, such as via Zigbee, Bluetooth, and the like. The power supply(ies) 432 may include a power interface for providing power to the remote communications device 306.

### Example Cloud Environment

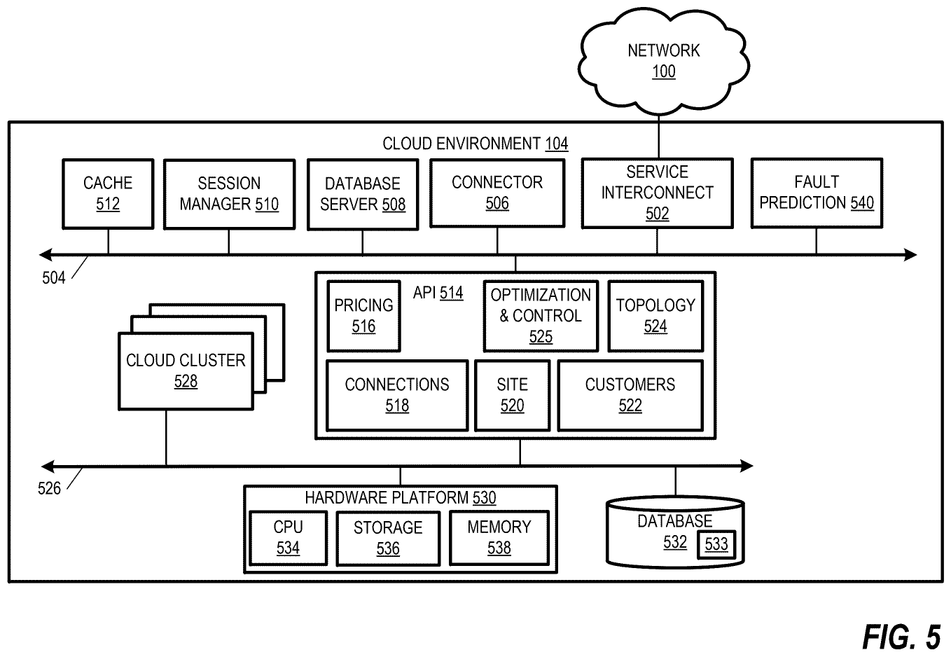

FIG. 5 depicts an example cloud environment for predicting a fault of an EVSE, according to aspects provided herein. As illustrated, the network 100 may couple to the cloud environment 104 via a service interconnect 502 that corresponds with the service interconnect 224 from FIG. 2. Similar to the service interconnect 224 from FIG. 2, the service interconnect 502 may be configured to facilitate an HTTP, TCP, and/or other communication portal through the network 100 to the edge environment 102 for the exchange of data between the edge environment 102 and the cloud environment 104. Additionally or alternatively, the service interconnect 502 may be configured to facilitate an HTTP, TCP, and/or other communication portal through the network 100 directly with an electric vehicle supply equipment (EVSE), such as charging station 112, for the exchange of data between the edge environment 102 and the EVSE. For example, in some such aspects, cloud environment 104 may be configured with the same or similar components as edge environment 102 (e.g., in addition or alternative to one or more components shown in FIG. 5) and configured to perform functions similar to edge environment 102, such that a separate edge environment 102 may not be needed.

The service interconnect 502 is coupled to a communication bus 504, which facilitates communication among various components of FIG. 5. Also connected to the communication bus 504 are a NATS connector 506, a database server 508, a session manager 510, a cache 512, a collection of services and application programming interfaces (APIs) 514, and a fault prediction component 540. The APIs 514 may include a pricing API 516, a connections API 518, a site API 520, a customers API 522, a topology API 524, and/or an optimization and control API 525. The APIs 514 may be implemented by hardware platform 530. Hardware bus 526 is coupled to a NATS cloud cluster 528, as well as the hardware platform 530 and a database 532. The hardware platform 530 may include one or more CPUs 534, one or more storage components 536, and one or more memory components 538. Though certain components of cloud environment 104 are depicted separate from hardware platform 530, they may be services or processes configured to run on hardware platform 530. Further, though certain components are illustrated as separate components, the functionality of such components may be combined into a single component and/or further divided among additional components.

The APIs 514 is a component of the cloud environment 104. As such, the APIs 514 (including the pricing API 516, the connections API 518, the site API 520, the customers API 522, the topology API 524, and/or the optimization and control API 525) may cause storage of and/or process site information, site topology, customers, connections to panels, constraints of panels, pricing information of each site, local forecasting services, optimization services, controller services, caching services, etc. The APIs 514 may also serve as a mobile backend by storing personal information of charge users (e.g., email, charging preferences, payment preferences, privileges, access, fleet information, etc.). The APIs 514 may additionally store peak charging configurations, data related to meter setup, etc. In some cases, the APIs 514 may also be responsible for tracking changes to EVSE connections and causing related changes to various types of data. For example, a newly connecting EVSE may create a new charging session, and a newly disconnecting EVSE may close a charging session. The connection and the disconnection may cause changes in payment information for user(s) of the connecting or disconnecting EVSE(s), for example, related to payment for energy usage. In some aspects, the pricing API 516 may be used for storing information related to pricing configuration of a charging site, such as the site 110 (of FIG. 1). Some examples of the information related to pricing configuration of a charging site may include, but not be limited to, cost for energy (e.g., $/kWh), cost for parking time (e.g., $/time-interval), cost for idle parking time (e.g., $/idle-time-interval), etc. In certain aspects, the site API 520 may be or include a service that provides an API to read or change information about a charging site (e.g., site name, address, etc.). The topology API 524 may be used for storing information related to topology of EVSEs, and may be utilized to track, for example, which EVSEs are connected to which electrical panels and whether any electrical panels may be subpanels of other panels. Such information may be utilized for load management. In some aspects, the optimization and control API 525 may be responsible for handling optimization requests, performing one or more optimization methods, and communicating the result of the optimization. For example, the optimization and control API 525 may be or include a service that may be executed when there is a newly connected or disconnected EVSE, such that an optimization may be performed to allocate (e.g., re-allocate) power according to updated state(s) of the EVSE(s). In some aspects, optimization and control API 525 may enable per-site configuration of the optimization and control parameters. For example, these parameters can be updated via API(s) 514 (e.g., optimization and control API 525) directly or via a front-end interface. These parameters may include different parameters for each optimization strategy as well as the grouping of strategies into stages. Moreover, optimization and control API 525 may be used to store (e.g., via database 532) input and output pairs (e.g., related to various optimization scenarios, where an input may correspond to a combination of the optimization configuration and system state and an output may correspond to a collection of parameters for how the system should operate, etc.) for subsequent analysis.

When a vehicle is plugged into a charging station 112 (FIG. 1), the edge session broker 218 (FIG. 2) may communicate connection information to the APIs 514. The connection information may include vehicle information, user information, charging station information, etc. The APIs 514 then create a charge session object, which is stored in the cache 512. The cache 512 sends the session data, along with topology constraints and the charge session object to the edge environment 102. The NATS connector 506 may additionally cause the NATS cloud cluster 528 to maintain the charge session object for retrieval by an interested party. As the session continues, the session manager 510 may be utilized to alter constraints of the session, which may cause the NATS cloud cluster 528 to update the charge session object.

When a user claims a previously created session with the mobile device 108c, the database server 508 may create a database entry (e.g., within the database 532) with the charge session, driver, energy request, willingness to pay, electricity purchased, etc. The NATS connector 506 may update the NATS cloud cluster 528 with the database entry. This data may then be sent to the edge environment 102. When the charge session ends (e.g., when the vehicle is unplugged), that action may be added to the database entry and the database entry may be moved from a current sessions list to a completed sessions list.

In certain aspects, the database 532 may include optimization data 533 related to, for example, optimization scenarios (e.g., past optimization scenarios which may be used for debugging and/or auditing the performance of a given optimization scheme).

As indicated above, the hardware platform 530 may represent hardware that may be utilized to execute the components described regarding FIG. 5. As such, the CPU(s) 534 may be configured as any processing unit for receiving and executing computer-readable instructions. The storage component(s) 536 may be configured as any hard drive or other local storage device. The memory component(s) 538 may be configured as any type of RAM, ROM, registers, etc. or the like.

In certain aspects, the fault prediction component 540 may implement one or more functions of the fault prediction system described herein with reference to, for example, FIGS. 6-8, below.

### Example Fault Prediction System

Certain aspects of a fault prediction system are described with reference to FIGS. 6-8. Some aspects may utilize a cloud computing environment (e.g., one or more components, such as fault prediction component 540, of the cloud environment 104 described herein with reference FIG. 5) to process large volumes of time series data, such as to run shapelet discovery or detection algorithms. For example, certain aspects may involve a continuous learning process to adapt to new data and update predictive models accordingly. Moreover, data from multiple sources, including EVSE metrics (e.g., current and voltage), environmental data (such as weather conditions), vehicle details, firmware information including firmware versions, and/or usage patterns, may be integrated into a machine learning feature set. This (e.g., comprehensive) dataset may then be analyzed to detect time series signatures (e.g., shapelets) that have correlations and predict potential future faults.

In certain aspects, the systems and methods described herein may use various algorithms for time series classification for shapelet discovery. These algorithms may identify short, significant sub-sequences within time series data, termed “shapelets”, which may be indicative of imminent faults. For example, historical data of detected fault codes may be used as a source of truth (e.g., ground truth). A time series feature set of the time ranges preceding these fault codes may be used in shapelet discovery process. Once shapelets have been identified, additional time series classification models may be trained to detect these shapelets in operations. Once a repository of saved shapelets is obtained, a periodic (e.g., daily) job may be run on most recent operational time series data to classify any of these known shapelet time series signatures. In such periodic classification process, identified shapelets may then be saved to a data storage system (e.g., a database) for future processing and alerting. In some aspects, predictive models may be managed through a continuous learning process, where newly discovered shapelets may be “tested” and, if proven effective, integrated into the operational model. Models that lead to high false-positive rates may be iteratively refined or discarded. A periodic job, for example, in the cloud environment may conduct shapelet discovery, updating predictive models based on recent data. The periodic operations may involve scanning active EVSE data (e.g., time series data) from previous minutes, hours, days, etc. to detect these shapelets, triggering alerts for potential faults which may then be addressed through preventive maintenance and support staff's follow-up investigation. It should be understood that in some cases a single detected shapelet may be indicative of an upcoming fault. In some cases, multiple shapelets occurring in a particular pattern, such as over a particular time period, may be indicative of an upcoming fault.

FIG. 6 depicts an example system 600 for predicting a fault of an EVSE, according to aspects provided herein. As depicted, system 600 includes data source 602, data integration component 604, data storage component 606, shapelet detection component 608, model training component 610, predictive model 612, user interface 614, monitoring component 616, and preventative maintenance component 618. In certain aspects, at least the predictive model 612 may utilize the cloud environment 104 (e.g., one or more components such as fault prediction component 540 and/or compute resources of the cloud environment 104) to process time series data in order to determine information relating to signatures (e.g., shapelets) for an impending fault of an EVSE as well as any relevant information such as a criticality level of the impending fault. The determined information may be provided through user interface 614 to be, for example, incorporated as part of a dashboard that may provide alerts and/or display data that may be validated by an engineer (e.g., as part of a human-in-the-loop process). In some cases, such an alert may be provided to a user interface that is accessible by a user (e.g., through a user application on a user device or a display on an EVSE or a charger, etc.), such as to provide a message to the user. Such a message may include an indication to stop using, or to not use, an EVSE or a charger where a fault was predicted to occur. In some cases, such an alert (or the determined information relating to the signatures or shapelets for an impending fault of an EVSE) may be used to (e.g., automatically) disable charge sessions at the EVSE, such as until a (preventative) service has been performed on the EVSE. In some aspects, the components of the system 600 may be software or hardware components, and the functionality described herein may be combined or separated into any suitable number of components. For example, one or more of the components may be software stored in memory and executing on one or more processors.

In certain aspects, data source 602 may provide to data integration component 604 time series data. Examples of the time series data may include EVSE metrics, EVSE usage patterns, weather data, etc. Accordingly, in some aspects, data source 602 may be more than one entity that provide parts of the time series data.

Data integration component 604 may process (e.g., preprocess) the time series data into feature set data, such as a machine learning feature set, which integrates data from multiple sources, including EVSE metrics (e.g., current and voltage), environmental data (such as weather conditions), vehicle details, firmware information including firmware versions, and usage patterns, etc.

Data storage component 606 (e.g., a database) may store the feature set data generated by data integration component 604.

Shapelet detection component 608 may utilize the feature set data stored on the data storage component 606 to detect shapelets in time series data.

Model training component 610 may utilize the detected shapelets to train and provide predictive model 612. In certain aspects, as discussed, only certain detected shapelets may be used for training, as not all shapelets detected may be indicative of a fault.

Predictive model 612 (e.g., a machine learning model, such as a fault detection machine learning model) may receive current time series data and/or shapelet data as input, and predict (e.g., detect or identify) a fault of an EVSE based on shapelet(s) included in the current time series data and/or shapelet data. Predictive model 612 may utilize one or more components and/or compute resources of the cloud environment 104.

Output of predictive model 612 may be provided to user interface 614 (a user dashboard), which may provide monitoring component 616 and/or preventative maintenance component 618. Monitoring component 616 may be used by an engineer for monitoring the detected or predicted data to validate the detected or predicted data, etc. Preventative maintenance component 618 may be used for providing preventative maintenance scheduling or alerts, where the validation of the detected or predicted data as well as any other action including the preventative maintenance alerts may be used as feedback for further training predictive model 612 via model training component 610.

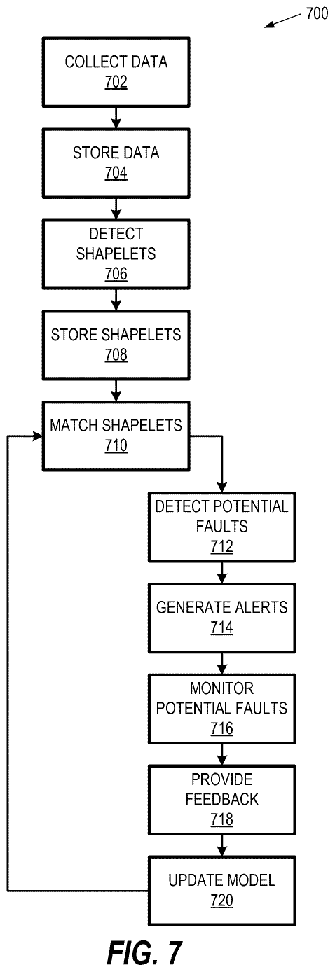

FIG. 7 depicts an example process flow 700 for predicting a fault of an EVSE, according to aspects provided herein.

At 702, data (e.g., time series data) may be collected. For example, the time series data may be collected from data source of FIG. 6.

At 704, the collected data may be stored, for example, by data storage component 606 of FIG. 6.

At 706, shapelets may be detected (e.g., periodically, such as monthly, etc.). For example, shapelets may be detected by shapelet detection component 608 of FIG. 6.

At 708, one or more of the detected shapelets may be stored. For example, a subset (e.g., less than all) of the detected shapelets may be determined, such as by a user, to be associated with a fault to be monitored and stored.

At 710, the detected shapelets may be matched to one or more portions of current time series data, for example, associated with one or more EVSEs and/or one or more sites (e.g., periodically, such as hourly, daily, etc.).

At 712, potential (e.g., impending) faults may be detected based on the matched shapelets from 710.

At 714, alerts may be generated based on the detected potential faults. An example of such alert may be to schedule a maintenance for an associated EVSE as an effort to mitigate a lengthy downtime from a fault status occurring for the EVSE.

At 716, the information regarding the detected potential faults may be monitored, for example, through user interface 614 of FIG. 6.

At 718, feedback may be provided based on the monitored information at 716.

At 720, a model may be refined and/or updated based on the feedback at 718.

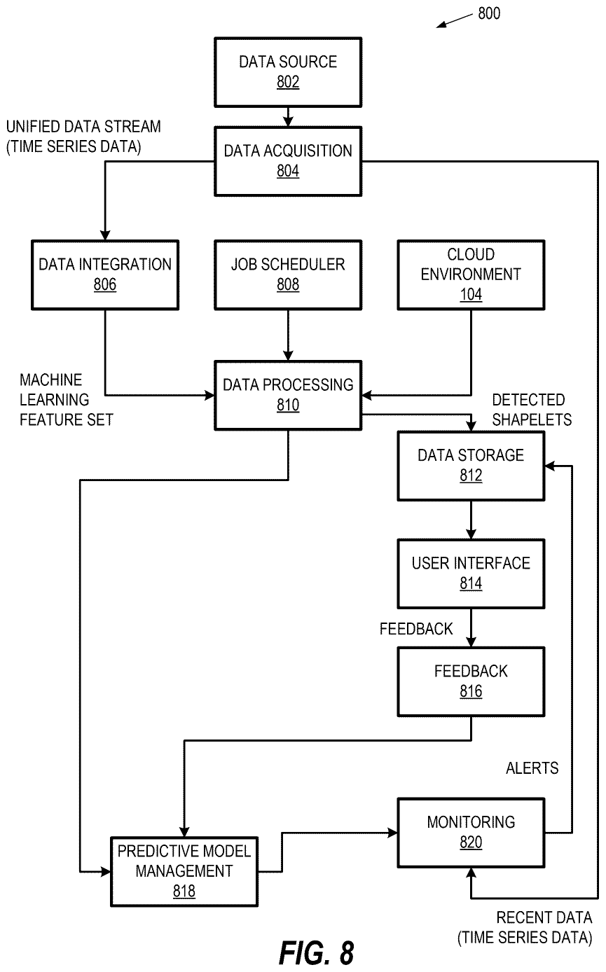

FIG. 8 depicts an example system 800 for predicting a fault of an EVSE, according to aspects provided herein. As depicted, system 800 includes data source 802, data acquisition component 804, data integration component 806, job scheduler 808, data processing component 810 (which may utilize one or more components and/or compute resources of the cloud environment 104), data storage component 812, user interface 814, feedback component 816, predictive model management component 818, and monitoring component 820. In some aspects, the components of the system 800 may be software or hardware components, and the functionality described herein may be combined or separated into any suitable number of components. For example, one or more of the components may be software stored in memory and executing on one or more processors.

Certain aspects of system 800 provide several features and solutions. For example, certain aspects provide advanced time series analysis for shapelet discovery or detection. Some aspects utilize specialized algorithms, such as to implement time series analysis for shapelet discovery algorithms. These algorithms may detect significant subsequences (“shapelets”) in time series data that are indicative of impending faults. Some aspects analyze high-frequency data, such as data collected at various frequencies (e.g., 1-second, 10-second, 30-second, 60-second intervals, etc.) to capture detailed operational patterns.

As another example, certain aspects provide integration of heterogeneous data sources. Some aspects provide comprehensive data collection, such as to gather diverse data, including electrical metrics (current, voltage, kWh delivered), environmental data (e.g., weather conditions), vehicle details, firmware versions, and usage patterns. Moreover, some aspects provide a unified analytical framework that integrates heterogeneous data into a cohesive machine learning feature set for comprehensive analysis.

As yet another example, certain aspects provide a cloud-based computational infrastructure that enables a scalable processing environment. Such processing environment may employ a cloud environment (e.g., the cloud environment 104) capable of handling large-scale, high-frequency data processing, and use parallel computing configurations to efficiently perform shapelet discovery and time series analysis. Scheduled (e.g., daily) jobs may be run to analyze recent data, discover new shapelets, and update predictive models.

As yet another example, certain aspects provide adaptive predictive modeling. Vendor-specific and global models may develop predictive models based on universally applicable shapelets and one(s) tailored to specific EVSE manufacturers and/or unit types. Accounts for unique fault patterns may be associated with different hardware. Moreover, the adaptive predictive modeling may provide continuous learning and refinement to continuously update models based on new data and feedback, improving accuracy over time.

As yet another example, certain aspects provide human-in-the-loop for false positive management based on an expert review process and/or feedback integration. The expert review process may involve engineers (e.g., support engineers) to review and monitor chargers flagged by the system, where the engineers may assess the flagged instances to determine if they represent true potential faults. The feedback integration may use human assessments to refine predictive models and reduce false positives over time.

As yet another example, certain aspects provide visualization and support tools, including a shapelet review dashboard and alerting mechanisms. The shapelet review dashboard may provide a user interface where support engineers can browse discovered shapelets, visualize time series signatures within example cases, and evaluate the uniqueness and relevance of shapelets. Moreover, the shapelet review dashboard may provide an access to statistics on the frequency of shapelet occurrences before faults. The alerting mechanisms may store identified shapelets in a database for future processing and generate alerts for potential faults. For example, only certain detected shapelets (or series of shapelets) may be used to train a predictive model used to determine whether a fault will occur, as only certain shapelets may be indicative of a fault to be alerted.

As yet another example, certain aspects provide optimized operational workflow that allows proactive maintenance scheduling and resource allocation. Some aspects may enable preemptive actions to address potential faults before they occur, and may improve maintenance efficiency by focusing on chargers that exhibit fault-indicative patterns. Moreover, some aspects may help allocate support and maintenance resources more effectively by prioritizing units at higher risk of failure. In some cases, based on the identified fault predictions, certain aspects of the present disclosure may further generate a health score or risk assessment for each EVSE unit, providing a quantifiable measure of its operational integrity and likelihood of future failure within a specified timeframe. This would enhance the site and/or charger management to be more predictive and less reactive.

By implementing these features and solutions, certain aspects may transform EVSE fault detection from a reactive process into a proactive one. Certain aspects may effectively address the technical challenges of analyzing high-frequency, high-volume time series data, integrating heterogeneous data sources, and adapting to various hardware types. The systems described herein may enhance overall EVSE reliability, reduce downtime, and lead to more efficient maintenance operations.

As described further herein, various types of data may be collected to detect shapelets. Such data may be related to various charger types, historical data associated with various charger types, vehicle information and EVSE firmware (FW) information (e.g., vehicle and EVSE FW pairing information), current delivered, expected current delivered, set points, voltage, meteorological information, charge summary (e.g., from charging sessions, such as charge records at certain intervals such as a rolling time (e.g., 5-minute) window, where for example, bursts of data indicating plugging and unplugging within a few seconds may correspond to “micro” sessions), EVSE metrics (e.g., fault codes such as warnings and/or critical alerts where charging cannot be completed), etc. Critical alerts may trigger collection of recent time series data (e.g., from the last 30 minutes, 1 hour, 2 hours, 3 hours, 4 hours, 5 hours, 6 hours, etc.), where the detection of fault codes, collection of recent time series data, and detection of shapelet(s) may be a method of feature engineering for detecting or predicting a fault of an EVSE.

In certain aspects, time-series data may have varying frequencies, and a subset of the collected time-series data may be obtained by a data integration and preprocessing logic described herein. In some aspects, jobs may be performed periodically (e.g., daily) to look for shapelets in time series data. In certain aspects, the systems described herein may use cloud-based resources. In some aspects, shapelets may be created by a data processing and analysis logic, and shapelets associated with faults may be stored by a storage component such as a database.

In certain aspects, a user interface may provide a mode of visualization, where many candidates of shapelets from a large amount of data (e.g., time series data) may be obtained, the candidates of shapelets and any related information may be stored, and information including a general shape of the shapelets (e.g., the candidates of shapelets), frequency of occurrences, associated fault codes, etc. may be fed into a database and then into the user interface. Engineers with domain knowledge may monitor the information provided via the user interface and provide feedback and/or validation (e.g., labeling) regarding the candidates of shapelets, which would build a training data set for supervised learning.

In certain aspects, a predictive model management component may be used to run time series classification around shapelets for detecting or predicting whether a shapelet (or group of shapelets) may need to be investigated as an indication of an impending fault of an EVSE. The prediction may be based on a shapelet in some cases. In some cases, the prediction may be based on a group of shapelets (e.g., including their timings, sequence and orders, etc.).

In some aspects, shapelet discovery may be converted into features for predictive models, and a variable (e.g., a binary variable) regarding the presence of a shapelet (e.g., as part of a vector) may be provided to a predictive model to predict a potential impending fault and any relevant criticality level. If critical, a maintenance task may be scheduled. If not critical, a normal operation may continue. An output of a predictive model may indicate whether a potential impending fault needs to be investigated (e.g., with an indication of a state or status of an energy asset such as an EVSE). Non-limiting examples of the output may include an indication of a type of fault, an indication of a severity of fault, an identification of a fault code or a fault category, an indication of a probability (e.g., a numerical representation of likelihood) of fault, and/or an indication of no fault.

Certain aspects provide a proactive fault detection system for EVSE that utilizes advanced time series analysis including shapelet discovery or detection techniques to predict faults before they occur. The system may integrate heterogeneous data sources—including high-frequency operational metrics, environmental conditions, vehicle details, firmware versions, and usage patterns—into a unified analytical framework. It may process this data using scalable cloud computing infrastructure to identify unique patterns (shapelets) indicative of impending faults. The predictive models may be continuously refined through a human-in-the-loop approach involving expert support engineers. The system may enhance EVSE reliability by enabling proactive maintenance and reducing downtime.

Various components of system 800 are now described as follows.

In certain aspects, data acquisition component 804 collects high-frequency operational data from EVSE units and integrates it with data from external data sources (data source 802). Example inputs for data acquisition component 804 may include, but are not limited to: EVSE operational metrics (e.g., current, voltage, power delivered, status codes, etc.), environmental data (e.g., weather conditions), vehicle details, firmware versions, and usage patterns. Example outputs from data acquisition component 804 may include, but are not limited to: unified data streams formatted for processing.

In certain aspects, data integration component 806 (which may be a data integration and preprocessing component) cleans, synchronizes, and preprocesses the collected data to create a cohesive dataset. Example processes of data integration component 806 may include, but are not limited to: data cleaning (e.g., handling missing or corrupt data), time synchronization across different data sources, and feature extraction and engineering. Example outputs from data integration component 806 may include, but are not limited to: machine learning feature set ready for analysis.

In certain aspects, system 800 provides a cloud-based computational infrastructure (e.g., utilizing the cloud environment 104), where its function may be to provide scalable computing resources to handle large-scale data processing and analysis. Such infrastructure may provide features such as parallel computing configurations, resource management for computational efficiency, etc. Its interaction may include, but is not limited to: hosting data processing component 810.

Data processing component 810 may also be referred to as a data processing and analysis component. In certain aspects, its function is to perform advanced time series analysis including shapelet discovery on the preprocessed data. Its example sub-components may include, but are not limited to: shapelet discovery engine, time series classification models, algorithms used, relevant libraries of methods for shapelet discovery, machine learning models for time series classification, etc. Example outputs may include, but are not limited to: identified shapelets, trained predictive models, etc.

In certain aspects, predictive model management component 818 manages the lifecycle of predictive models, including training, validation, deployment, and refinement. Its example processes may include, but are not limited to: continuous learning with new data, model evaluation (e.g., assessing accuracy, recall, false positives), and model updating or discarding based on performance. Its example outputs may include, but are not limited to: updated and validated predictive models ready for operational deployment

In certain aspects, job scheduler 808 (e.g., a periodic job scheduler) orchestrates the timing and execution of data processing tasks. Its example features may include, but are not limited to: running periodically (e.g., daily or as per requirements) and managing resource allocation for scheduled tasks. Its example interaction may include, but is not limited to: triggering the data processing component 810.

In certain aspects, monitoring component 820 applies the predictive models to recent operational data to detect potential faults. Its example process may include, but is not limited to: scanning of recent EVSE data for known shapelets, classification of detected shapelets as potential fault indicators, etc. Its example outputs may include, but are not limited to: alerts and notifications for potential faults and data stored in a database for further analysis.

In certain aspects, data storage component 812 stores identified shapelets, predictive models, operational data, and/or alerts. Its example features may include, but are not limited to: structured storage for efficient retrieval, historical data archiving for trend analysis, etc. Its example interaction includes, but is not limited to: interfacing with user interface 814.

In certain aspects, user interface 814 (which may also be referred to as or include a user interface and visualization component or a shapelet review dashboard) may provide support engineers with tools to visualize and analyze detected shapelets and potential faults. Its example features may include, but are not limited to: interactive dashboards, visualization of time series data and shapelets, statistical reports on shapelet occurrences and fault correlations, etc. Its example outputs may include, but are not limited to: insights for support engineers to make informed decisions.

In certain aspects, feedback component 816 (which may be referred to as a human-in-the-loop feedback component) incorporates expert feedback from support engineers to refine predictive models. Its example process may include, but is not limited to: collecting annotations and classifications from engineers and updating models based on human feedback. Its example outputs may include, but are not limited to: improved model accuracy and reduced false positives.

Description of component interactions and workflow follows.

For data acquisition and integration, EVSE units may continuously generate high-frequency operational data. The data acquisition component 804 may collect this data (e.g., via application programming interfaces (APIs) set up for data extraction). Environmental data and other data from other external sources may also be collected. The data integration component 806 may clean and synchronize the data, preparing it for analysis.

For data processing and shapelet discovery, the job scheduler 808 may trigger the data processing component 810 periodically (e.g., daily). For example, a shapelet discovery engine may analyze historical fault data to identify shapelets, where it may use time series segments preceding known faults as input and apply algorithms to discover significant subsequences. Identified shapelets may be stored in the data storage component 812.

For predictive model training and management, time series classification models may be trained using the discovered shapelets. The predictive model management component 818 may validate and update models, where models with high accuracy and acceptable false positive rates may be deployed and underperforming models may be refined or discarded.

For operational monitoring and fault prediction, the monitoring component 820 may scan recent operational data using the deployed predictive models. When a known shapelet is detected in the data, an alert may be generated, and the event may be logged in the data storage component 812.

For visualization and human feedback, support engineers may access the shapelet review dashboard (e.g., via user interface 814) to: visualize detected shapelets within the time series data, assess the uniqueness and relevance of shapelets, and review statistics on shapelet occurrences and their correlation with faults. Engineers may provide feedback via the feedback component 816, such as to confirm or dismiss potential fault predictions and annotate data for future model refinement.

For model refinement and continuous learning, feedback from support engineers may be used to update the predictive models in the predictive model management component 818. The system may learn from human classifications, improving accuracy over time. New shapelets may be discovered and added to the models as more data is collected.

Example inputs for system 800 may include, but are not limited to high-frequency EVSE operational data (current, voltage, power delivered, status codes), environmental data (temperature, humidity, weather conditions), vehicle details (make, model, charging capabilities), firmware versions and updates, usage patterns (charging session durations, frequencies), driver feedback (charge session rating/feedback), etc. Example outputs for system 800 may include, but are not limited to: identified shapelets indicative of potential faults, predictive models for fault detection, alerts and notifications for potential faults, visualizations and dashboards for support engineers, reports on system performance and fault prediction accuracy, etc.

Certain algorithms and techniques may be used for system 800. For example, shapelet discovery algorithms may identify significant subsequences in time series data that correlate with faults. These may be implemented by using known libraries, analyzing labeled time series segments preceding known faults, extracting shapelets that are statistically significant, etc.

Time series classification models may classify new time series data based on the presence of known shapelets. These may be implemented by training models using labeled data with identified shapelets, algorithms including Random Forest, Gradient Boosting, or Neural Networks specialized for time series data.

Example data preprocessing techniques prepare raw data for analysis. Example processes include, but are not limited to: handling missing values and outliers, normalizing or standardizing data, time alignment and synchronization, etc.

For parallel computing and scalability, its purpose may be to efficiently process large volumes of data. Its implementation may include, but is not limited to: using cloud computing services that support parallel processing, distributing computations across multiple nodes or processors, etc.

For human-in-the-loop process, the role of support engineers may include, but is not limited to: reviewing alerts generated by the system, assessing whether flagged chargers are truly at risk of fault, providing annotations and feedback on the accuracy of predictions, etc. For integration with predictive models, feedback is collected and analyzed to adjust model parameters. This process helps in reducing false positives and improving model precision, and supports continuous learning and adaptation to new fault patterns.

User interface and visualization details are now described.

Shapelet review dashboard features may include, but are not limited to: interactive visualization (e.g., time series plots showing operational data with detected shapelets highlighted and ability to zoom in on specific time intervals), shapelet library (e.g., repository of all discovered shapelets with metadata, search and filter capabilities based on various criteria (e.g., frequency, fault correlation)), statistical insights (e.g., charts and graphs showing shapelet occurrence rates, correlation metrics between shapelets and specific faults, etc.), annotation tools (e.g., options for engineers to add notes or classifications to shapelets, track changes and feedback over time, etc.).

An alert management may include, but is not limited to: a notification system (e.g., real-time alerts sent via email, SMS, or within the dashboard, prioritization based on the severity or likelihood of faults, etc.) and incident tracking (e.g., log of all alerts with status updates (e.g., under review, confirmed fault, false positive), integration with maintenance scheduling systems, etc.).

An example data flow description is now provided. The step-by-step data flow includes: data collection (EVSE units and external sources generate data, and data is collected via APIs and sent to the cloud infrastructure), followed by data integration and preprocessing (raw data is cleaned and synchronized, and features are extracted for analysis), followed by shapelet discovery (historical fault data is analyzed, and shapelets are discovered and stored), followed by model training (predictive models are trained using the identified shapelets), followed by operational data monitoring (recent operational data is scanned for known shapelets, and detected shapelets trigger potential fault alerts), followed by alerts and visualization (alerts are generated and sent to support engineers, and engineers use the dashboard to review and analyze), followed by feedback and model refinement (engineers provide feedback on alerts, and models are updated based on feedback), followed by continuous improvement (the system iterates through this process, continuously improving over time). It should be noted that similar data flows may be used, with fewer, additional, or different steps.

Accordingly, certain aspects provide a comprehensive solution for proactive fault detection in EVSE systems by integrating advanced time series analysis, scalable computing infrastructure, and human expertise. By meticulously processing and analyzing high-frequency operational data alongside diverse external factors, some aspects predict faults before they occur, significantly enhancing system reliability and operational efficiency. The detailed components and their interactions outlined above demonstrate how certain aspects of the present disclosure accomplish various objectives through a combination of innovative technologies and processes described herein.

### Example Method of Predicting a Fault of an Evse

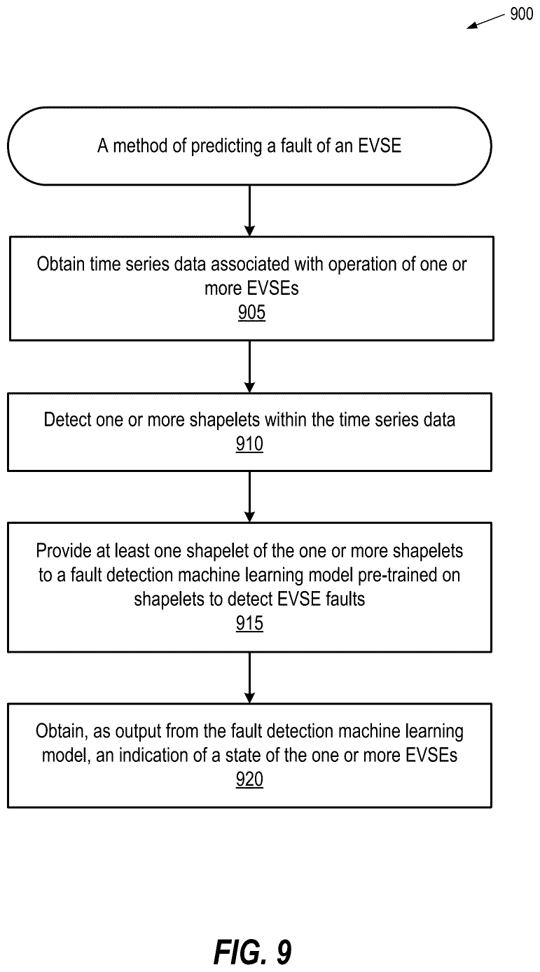

FIG. 9 depicts an example flowchart illustrating a method for predicting a fault of an EVSE, according to aspects provided herein. The method 900 may be performed by a core device 302 of FIGS. 3A-3C, for example, by utilizing one or more components of edge environment 102 described herein with respect to FIG. 2 and/or one or more components of cloud environment 104 described herein with respect to FIG. 5.

Method 900 begins at block 905 with obtaining time series data associated with operation of one or more EVSEs, such as described with respect to FIGS. 6, 7, or 8.

Method 900 then proceeds to block 910 with detecting one or more shapelets within the time series data, such as described with respect to FIGS. 6, 7, or 8.

Method 900 then proceeds to block 915 with providing at least one shapelet of the one or more shapelets to a fault detection machine learning model pre-trained on shapelets to detect EVSE faults, such as described with respect to FIGS. 6, 7, or 8.

Method 900 then proceeds to block 920 with obtaining, as output from the fault detection machine learning model, an indication of a state of the one or more EVSEs, such as described with respect to FIGS. 6, 7, or 8.

In some aspects, the time series data comprises one or more of: one or more operational parameters of the one or more EVSEs; or one or more environmental factors associated with the one or more EVSEs.

In some aspects, the one or more operational parameters comprise one or more of: offered current; delivered current; voltage; connector status; connection status; contactor status; offered power; delivered power; or EVSE status. In certain aspects, contactor status may refer to the state of electrical contactor(s) inside EVSE that control the flow of electricity to an EV. In certain aspects, offered current/power may refer to current/power sent to EVSE as set points, while delivered current/power may refer to current/power sent from EVSE to an EV (e.g., drawn by an EV or accepted by a battery on an EV). For example, an EV may draw more current than a current of an optimized set point. In another example, a battery on an EV (which may be nearly full) may accept less current than a current of an optimized set point.

In some aspects, the one or more environmental factors comprise weather data.

In some aspects, block 910 is performed, at least in part, by a time series classifier.

In some aspects, the one or more shapelets comprise a plurality of shapelets; and the at least one shapelet comprises a subset of the plurality of shapelets.

In some aspects, method 900 further includes selecting, as the subset of the plurality of shapelets, any of the plurality of shapelets included in a defined set of shapelets.

In some aspects, method 900 further includes providing, to the fault detection machine learning model, time series information associated with the at least one shapelet.

In some aspects, the indication of the state of the one or more EVSEs comprises one or more of: an indication of a type of fault; an indication of a severity of fault; an identification of a fault code or a fault category; an indication of a probability of fault; or an indication of no fault.

In some aspects, method 900 further includes transmitting, to a user interface, an indication of an alert based on the state of the one or more EVSEs, wherein the state of the one or more EVSEs comprises an impending fault.

In some aspects, method 900 utilizes time series analysis for shapelet discovery or detection to proactively identify shapelets indicative of upcoming faults, resulting in several technical benefits, such as: (1) higher recall in fault prediction, enabling operators to monitor potential fault candidates closely; (2) reduction in unnecessary downtime by allowing preventive maintenance before faults occur (e.g., based on the detected or identified signatures indicative of the upcoming faults); and (3) customization and adaptability to specific EVSE hardware, enabling detection of unique fault patterns across different EVSE or system types and sites; as well as other technically beneficial advantages that are described herein.

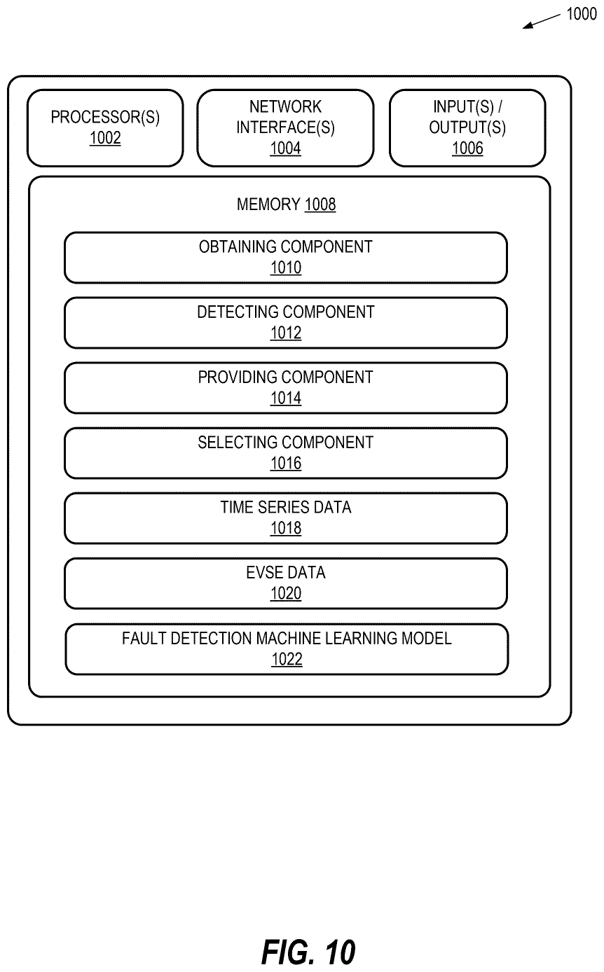

In some aspects, the method 900 may be performed by an apparatus or a processing system, for example, by utilizing one or more components of processing system 1000 described herein with respect to FIG. 10.

### Example Processing System for Predicting a Fault of an EVSE

FIG. 10 depicts an example processing system 1000 configured to perform the methods described herein.

Processing system 1000 may include one or more processors 1002. Generally, the one or more processors 1002 may be configured to execute computer-executable instructions (e.g., software code) to perform various functions, as described herein.

Processing system 1000 may further include one or more network interfaces 1004, which generally provide data access to any sort of data network, including personal area networks (PANs), local area networks (LANs), wide area networks (WANs), the internet, and the like.

Moreover, processing system 1000 may include input(s) and output(s) 1006, which generally provide means for providing data to and from processing system 1000, such as via connection to computing device peripherals, including user interface peripherals.

Processing system 1000 may also include one or more memories 1008 comprising various components. In this example, the one or more memories 1008 may include obtaining component 1010, detecting component 1012, providing component 1014, and selecting component 1016.

In certain aspects, obtaining component 1010 is configured to obtain time series data 1018 associated with operation of one or more EVSEs, for example, as described in FIG. 9 with reference to block 905. In certain aspects, detecting component 1012 is configured to detect one or more shapelets within the time series data, for example, as described in FIG. 9 with reference to block 910. In certain aspects, providing component 1014 is configured to provide at least one shapelet of the one or more shapelets to a fault detection machine learning model 1022 pre-trained on shapelets to detect EVSE faults, for example, as described in FIG. 9 with reference to block 915. In certain aspects, obtaining component 1010 is configured to obtain, as output from the fault detection machine learning model 1022, an indication of a state of the one or more EVSEs (e.g., EVSE data 1020), as described in FIG. 9 with reference to block 920.

Processing system 1000 may be implemented in various ways. For example, processing system 1000 may be implemented as a computing device 402 within a core device 302, described herein with respect to FIGS. 3A-3C and 4A. In various aspects, one or more aspects may be omitted from, added to, or substituted from processing system 1000.

### EXAMPLE CLAUSES

Implementation examples are described in the following numbered clauses:
Clause 1: A method of predicting a fault of an EVSE, the method comprising: obtaining time series data associated with operation of one or more EVSEs; detecting one or more shapelets within the time series data; providing at least one shapelet of the one or more shapelets to a fault detection machine learning model pre-trained on shapelets to detect EVSE faults; and obtaining, as output from the fault detection machine learning model, an indication of a state of the one or more EVSEs.
Clause 2: The method in accordance with Clause 1, wherein the time series data comprises one or more of: one or more operational parameters of the one or more EVSEs; or one or more environmental factors associated with the one or more EVSEs.
Clause 3: The method in accordance with Clause 2, wherein the one or more operational parameters comprise one or more of: offered current; delivered current; voltage; connector status; connection status; contactor status; offered power; delivered power; or EVSE status.
Clause 4: The method in accordance with Clause 2, wherein the one or more environmental factors comprise weather data.
Clause 5: The method in accordance with any one of Clauses 1-4, wherein the detecting is performed, at least in part, by a time series classifier.
Clause 6: The method in accordance with any one of Clauses 1-5, wherein: the one or more shapelets comprise a plurality of shapelets; and the at least one shapelet comprises a subset of the plurality of shapelets.
Clause 7: The method in accordance with Clause 6, further comprising: selecting, as the subset of the plurality of shapelets, any of the plurality of shapelets included in a defined set of shapelets.
Clause 8: The method in accordance with any one of Clauses 1-7, further comprising: providing, to the fault detection machine learning model, time series information associated with the at least one shapelet.
Clause 9: The method in accordance with any one of Clauses 1-8, wherein the indication of the state of the one or more EVSEs comprises one or more of: an indication of a type of fault; an indication of a severity of fault; an identification of a fault code or a fault category; an indication of a probability of fault; or an indication of no fault.
Clause 10: The method in accordance with any one of Clauses 1-9, further comprising transmitting, to a user interface, an indication of an alert based on the state of the one or more EVSEs, wherein the state of the one or more EVSEs comprises an impending fault.
Clause 11: One or more apparatuses, comprising means for performing a method in accordance with any one of Clauses 1-10.
Clause 12: A processing system, comprising means for performing a method in accordance with any one of Clauses 1-10.
Clause 13: A processing system, comprising: one or more memories comprising computer-executable instructions; and one or more processors configured to execute the computer-executable instructions and cause the processing system to perform a method in accordance with any one of Clauses 1-10.

Clause 14: A non-transitory computer-readable medium comprising computer-executable instructions that, when executed by a processor of a processing system, cause the processing system to perform a method in accordance with any one of Clauses 1-10.

Clause 15: A computer program product embodied on a computer-readable storage medium comprising code for performing a method in accordance with any one of Clauses 1-10.

Clause 16: A processing system, comprising: one or more memories; and one or more processors, coupled to the one or more memories, configured to cause the processing system to perform a method in accordance with any one of clauses 1-10.

### ADDITIONAL CONSIDERATIONS

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) (logic) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a memory,” “the processor,” “the memory,” etc.), unless otherwise specifically stated, should be understood to refer to one or more elements (e.g., “one or more processors,” “one or more memories,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., a system) to perform functions, one element may be configured to cause the other element to perform all functions, or more than one element may collectively be configured to cause the other element to perform the functions. Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

While particular aspects and aspects of the present disclosure have been illustrated and described herein, various other changes and modifications can be made without departing from the spirit and scope of the disclosure. Moreover, although various aspects have been described herein, such aspects need not be utilized in combination. Accordingly, it is therefore intended that the appended claims cover all such changes and modifications that are within the scope of the aspects shown and described herein.

What is claimed is:

1. A method of predicting a fault of an electric vehicle supply equipment (EVSE), the method comprising:
obtaining time series data associated with operation of one or more EVSEs;
detecting one or more shapelets within the time series data;
providing at least one shapelet of the one or more shapelets to a fault detection machine learning model pre-trained on shapelets to detect EVSE faults; and
obtaining, as output from the fault detection machine learning model, an indication of a state of the one or more EVSEs.

2. The method of claim 1, wherein the time series data comprises one or more of:
one or more operational parameters of the one or more EVSEs; or
one or more environmental factors associated with the one or more EVSEs.

3. The method of claim 2, wherein the one or more operational parameters comprise one or more of:
offered current;
delivered current;
voltage;
connector status;
connection status;
contactor status;
offered power;
delivered power; or
EVSE status.

4. The method of claim 2, wherein the one or more environmental factors comprise weather data.

5. The method of claim 1, wherein the detecting is performed, at least in part, by a time series classifier.

6. The method of claim 1, wherein:
the one or more shapelets comprise a plurality of shapelets; and
the at least one shapelet comprises a subset of the plurality of shapelets.

7. The method of claim 6, further comprising:
selecting, as the subset of the plurality of shapelets, any of the plurality of shapelets included in a defined set of shapelets.

8. The method of claim 1, further comprising:
providing, to the fault detection machine learning model, time series information associated with the at least one shapelet.

9. The method of claim 1, wherein the indication of the state of the one or more EVSEs comprises one or more of:
an indication of a type of fault;
an indication of a severity of fault;
an identification of a fault code or a fault category;
an indication of a probability of fault; or
an indication of no fault.

10. The method of claim 1, further comprising transmitting, to a user interface, an indication of an alert based on the state of the one or more EVSEs, wherein the state of the one or more EVSEs comprises an impending fault.

11. A processing system, comprising: one or more memories; and one or more processors, coupled to the one or more memories, configured to cause the processing system to:
obtain time series data associated with operation of one or more EVSEs;
detect one or more shapelets within the time series data;
provide at least one shapelet of the one or more shapelets to a fault detection machine learning model pre-trained on shapelets to detect EVSE faults; and
obtain, as output from the fault detection machine learning model, an indication of a state of the one or more EVSEs.

12. The processing system of claim 11, wherein the time series data comprises one or more of:
one or more operational parameters of the one or more EVSEs; or
one or more environmental factors associated with the one or more EVSEs.

13. The processing system of claim 12, wherein the one or more operational parameters comprise one or more of:
offered current;
delivered current;
voltage;
connector status;
connection status;
contactor status;
offered power;
delivered power; or
EVSE status.

14. The processing system of claim 12, wherein the one or more environmental factors comprise weather data.

15. The processing system of claim 11, wherein the detection is performed, at least in part, by a time series classifier.

16. The processing system of claim 11, wherein:
the one or more shapelets comprise a plurality of shapelets; and
the at least one shapelet comprises a subset of the plurality of shapelets.

17. The processing system of claim 16, wherein the one or more processors are further configured to cause the processing system to:
select, as the subset of the plurality of shapelets, any of the plurality of shapelets included in a defined set of shapelets.

18. The processing system of claim 11, wherein the one or more processors are further configured to cause the processing system to:
provide, to the fault detection machine learning model, time series information associated with the at least one shapelet.

19. The processing system of claim 11, wherein the indication of the state of the one or more EVSEs comprises one or more of:
an indication of a type of fault;
an indication of a severity of fault;
an identification of a fault code or a fault category;
an indication of a probability of fault; or
an indication of no fault.

20. The processing system of claim 11, wherein the one or more processors are further configured to cause the processing system to transmit, to a user interface, an indication of an alert based on the state of the one or more EVSEs, wherein the state of the one or more EVSEs comprises an impending fault.
